(19) United States
(12) Patent Application Publication
(10) Pub. No.: US 2016/0064351 A1
(43) Pub. Date: Mar. 3, 2016

(54) WIRE BONDING USING ELEVATED BUMPS FOR SECURING BONDS

(71) Applicant: SKYWORKS SOLUTIONS, INC., Woburn, MA (US)

(72) Inventor: Aldrin Quinones GARING, Mexicali (MX)

(21) Appl. No.: 14/474,129

(22) Filed: Aug. 30, 2014

(51) Int. Cl. H01L 23/00; H04M 1/02

(52) U.S. Cl. CPC H01L 24/48; H01L 24/08; H01L 24/16; H01L 24/85; H01L 24/81; H04M 1/0277; H01L 2224/48644

(57) ABSTRACT

In accordance with some embodiments, the present disclosure relates to improving the integrity of interconnections between electronic components. In some embodiments, a stitch bond can be secured by a ball or bump placed over the stitch bond. This results in forming strong, uniform interconnections and reducing or eliminating weak bonds. Further, in cases when interconnections are not formed correctly, bonding material can be recovered and reused. Efficiency is improved, yields are increased, and cost savings are achieved.

### TECHNICAL FIELD

The present disclosure relates generally to semiconductor fabrication and packaging. More specifically, the present disclosure relates to improved wire bonding that uses elevated bumps.

### BACKGROUND

Wire bonding is a common way of making electrical interconnections between electronic components, such as integrated circuits and printed circuit boards (PCB), during fabrication and packaging of semiconductor devices. Wire bonding involves using a wire (e.g., copper, gold, silver, alloyed aluminum, etc.) to form an interconnection between respective contacts. Wire bonding is generally considered to be cost-effective and flexible. Wire bonding can be automated by using a wire bonding machine (also known as wire bonders). However, a number of problems may arise during wire bonding process and cause formation of weak bonds, particularly when stitch bonding is used. For example, contaminated capillary, low parameter setting of the wire bonding machine, cap bond offset, use of long wires, etc. can cause formation of unreliable bonds. Weak bonds result in diminished yields, loss of material (e.g., wire), unreliable interconnections, and so on.

### SUMMARY

In accordance with some embodiments, the present disclosure relates to a method of forming a wire bond connection between a first contact and a second contact using a wire bonding machine. In certain implementations, the method includes bonding a wire to the first contact, placing a first ball on the second contact, forming a stitch bond to connect the wire to the second contact, with the stitch bond formed over the first ball. The method further includes forming a ball bond by placing a second ball over the stitch bond, thereby securing the stitch bond. In some variations, the method also includes performing an integrity test of the connection between the first contact and the second contact, and in response to determining that the integrity test had failed, recovering the wire for reuse in forming a wire bond connection. The integrity test can be a wire pull test. In some aspects, the first contact is a contact of a substrate and the second contact is a contact of a die. In other aspects, the first contact is a contact of a first die and the second contact is a contact of a second die.

Certain embodiments of the present disclosure relate to a chip package. In some aspects, the package includes a substrate configured to receive a plurality of components, the substrate including a substrate contact and a die supported by the substrate, the die including a die contact. The package further includes a wire interconnecting the die and the substrate, the wire bonded to the die contact by a stitch bond formed over a first ball placed on the die contact, and a ball bond formed by a second ball placed over the stitch bond.

Some embodiments of the present disclosure relate to a multi-chip package. In certain implementations, the package includes a first die including a first die contact, a second die including a second die contact, and a substrate configured to support the first die and the second die. The package further includes a wire interconnecting the first die and the second die, the wire bonded to the second die contact by a stitch bond formed over a first ball placed on the second die contact, and a ball bond formed by a second ball placed over the stitch bond.

Some implementations of the present disclosure relate to a wireless device. In certain aspects, the wireless device includes an antenna configured to transmit and receive signals, a battery configured to power the wireless device, and a circuit board including a first die having a first die contact, a second die having a second die contact. The wireless device further includes a wire interconnecting the first die and the second die, the wire bonded to the second die contact by a stitch bond formed over a first ball placed on the second die contact, and a ball bond formed by a second ball placed over the stitch bond.

### BRIEF DESCRIPTION OF THE DRAWINGS

Throughout the drawings, reference numbers are reused to indicate correspondence between referenced elements. The drawings are provided to illustrate embodiments of the inventive subject matter described herein and not to limit the scope thereof.

FIGS. 1A-1C illustrate wire bond interconnections of electronic components in accordance with aspects of the present disclosure.

FIGS. 2A-2C illustrate wire bond interconnections of two dies in accordance with aspects of the present disclosure.

FIGS. 3A-3B illustrate wire bond interconnections of a die and a substrate in accordance with aspects of the present disclosure.

FIGS. 4A-4C illustrate wire bond interconnections of two dies using long wires in accordance with aspects of the present disclosure.

FIGS. 5A-5B illustrate wire bond interconnections in accordance with aspects of the present disclosure.

FIGS. 6A-6C illustrate test results of wire bond interconnections in accordance with aspects of the present disclosure.

FIG. 7 illustrates a process of forming wire bond interconnections in accordance with aspects of the present disclosure.

FIG. 8 illustrates a module in accordance with aspects of the present disclosure.

FIG. 9 illustrates a wireless device in accordance with aspects of the present disclosure.

### DETAILED DESCRIPTION

The headings provided herein, if any, are for convenience only and do not necessarily affect the scope or meaning of the claimed invention.

### Overview

Embodiments of the present disclosure provide systems and methods for improving the integrity of interconnections between electronic components. In some embodiments, a wire can be bonded to a first contact or connection and looped to the second contact or connection. The first ball can be formed or placed on the second contact. A stitch bond can be formed to connect the wire to the second contact. A ball bond can be formed by placing a second ball over the stitch bond. Advantageously, embodiments of the present disclosure provide for improved interconnections (e.g., wire bonds) as compared to traditional approaches, such as stitch bonds. These improvements encompass forming high integrity, strong, and consistent interconnections and reducing or eliminating weak bonds. Further, in cases when interconnections are not formed correctly, material (e.g., wire) can be recovered and reused. This improves efficiency, increases yields (e.g., by reducing defective parts per million or DPPM counts), and provides cost savings.

### Improved Wire Bonding

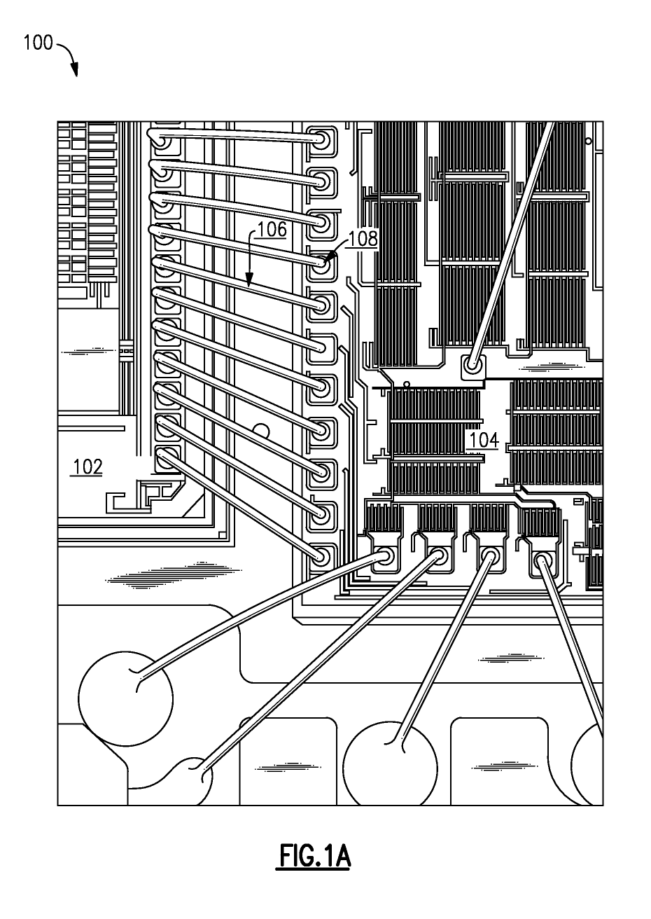

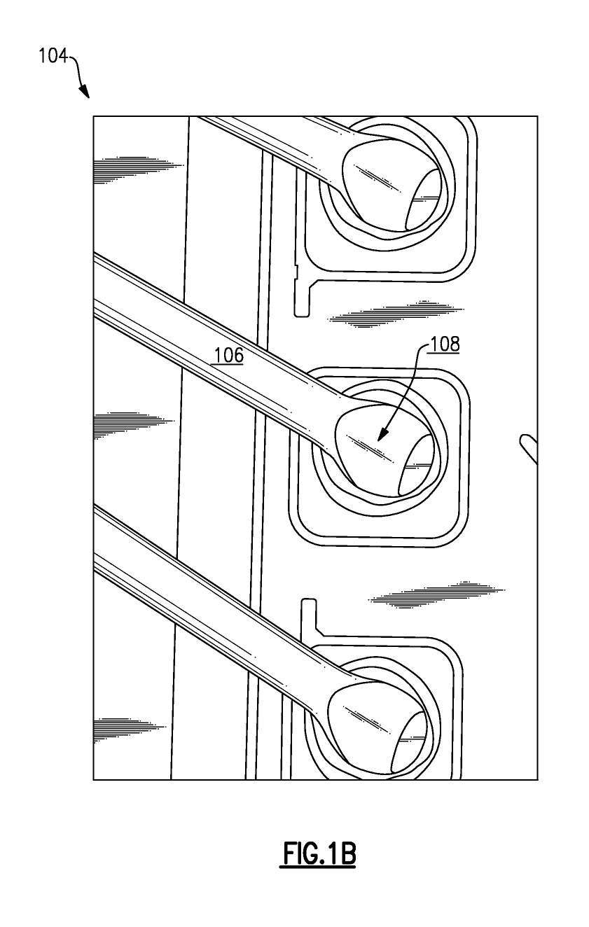

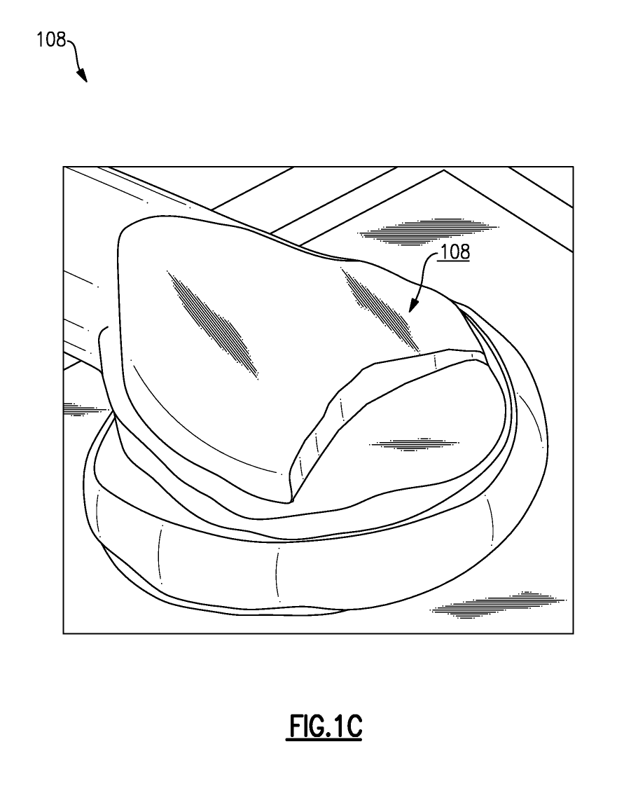

FIGS. 1A-1C illustrate wire bond interconnections 100 of electronic components in accordance with aspects of the present disclosure. As is shown in FIG. 1A, two dies 102 and 104 are interconnected by wires 106. Bonds 108 are formed on connectors of the die 104. FIGS. 1B and 1C illustrates a closeup of bond 108, which can be a stitch bond formed over a connector or over a ball or bump placed on the connector. Conductive wires 106 can be made out of gold, silver, copper, aluminum, etc. Conductive balls or bumps can similarly be made out of gold, silver, copper, aluminum, etc.

According to some embodiments, elevated bump (EBS) is a wire bonding process that combines formation of a bump with SSB (stand-off stitch bonding) or BSOB (ball stitch on ball bonding). SSB and BSOB can also be referred to as SOB (stitch over bump). In some aspects, SSB or BSOB can be used for making interconnections by placing a conductive ball over a connector (e.g., a lead frame connector), and making a stitch bond (also referred to as wedge bond, tail bond, etc.) over the ball. However, as is illustrated in FIGS. 1B and 1C, the bond 108 (e.g., stitch bond) may not have adequate integrity. For example, during testing of the interconnections, such as during non-destructive wire pull testing, the bond may break, dislodge, or otherwise become unreliable. Other types of testing can be performed, including destructive wire pull, first bond ball pull, stud bump ball pull, high force pull, shear testing, light scanning, electron microscope scanning, and so on.

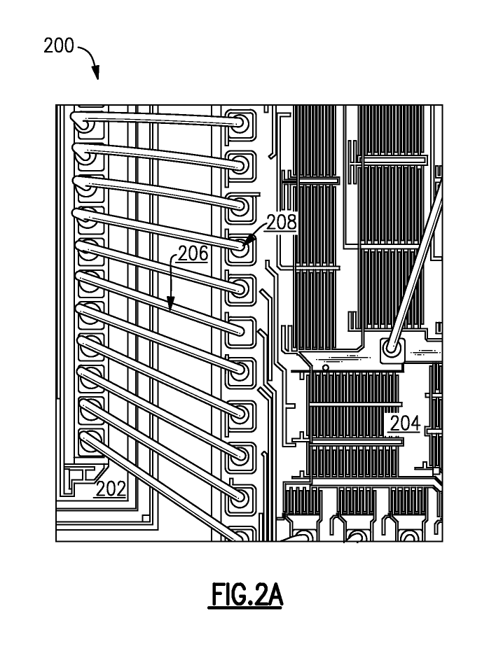

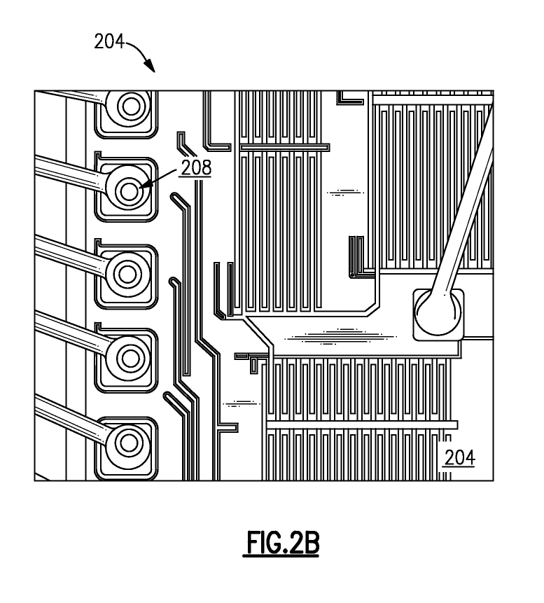

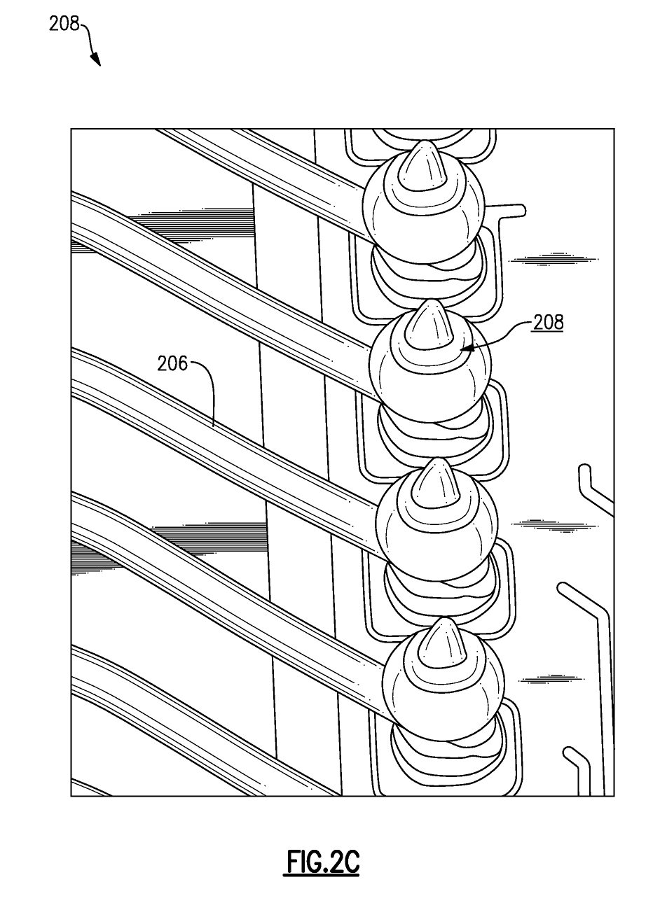

FIGS. 2A-2C illustrate wire bond interconnections 200 of two dies in accordance with aspects of the present disclosure. As is shown in FIG. 2A, two dies 202 and 204 are interconnected by conductive wires 206. Conductive bonds 208 are formed on the connectors of the die 204. As is illustrated in FIGS. 2B and 2C, a conductive ball or bump is placed over the stitch bond in order to provide a more secure and higher integrity bond 208. This type of bond can be referred to as a bond secured with an elevated bump or elevated ball. In some embodiments, elevated bump bonding results in more robust, reliable, and consistent higher integrity bonds when compared to stitch bonding.

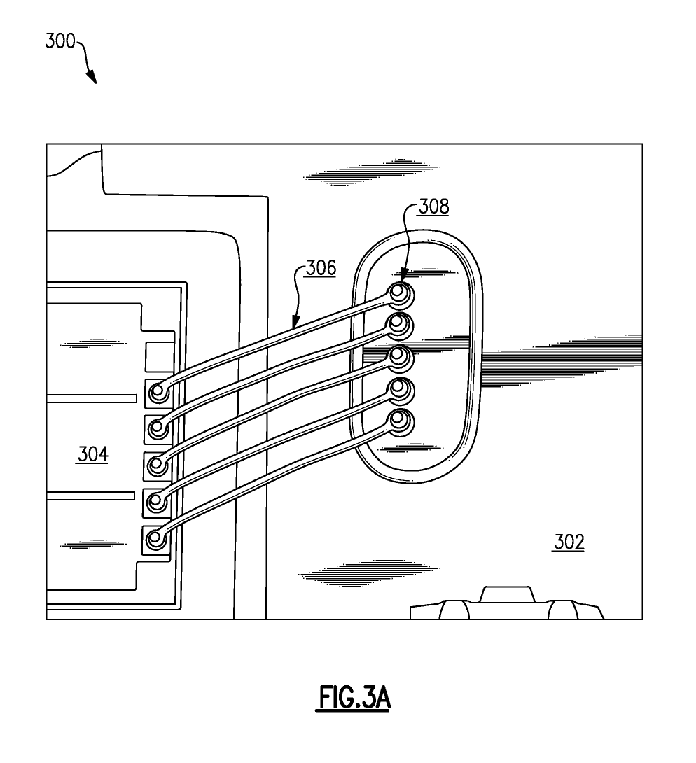

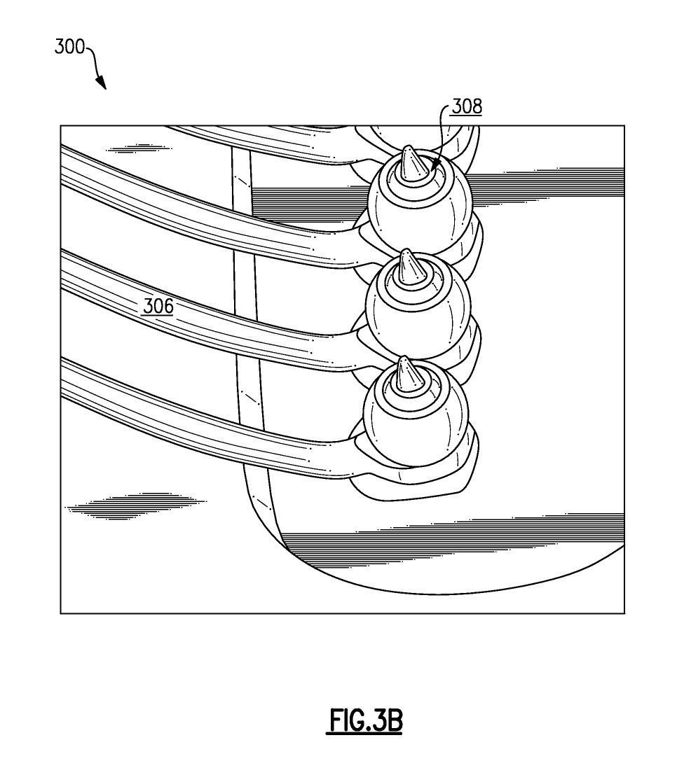

FIGS. 3A-3B illustrate wire bond interconnections 300 of a die and a substrate in accordance with aspects of the present disclosure. As is shown in FIG. 3A, the die 304 is electrically connected to the substrate 302 by conductive wires 306. In some embodiments, the substrate can be part of a printed circuit board (PCB). Conductive bonds 308 are formed on the connectors (e.g., signal, power, ground, etc.) of the substrate 302. As is illustrated in FIGS. 3B and 3C, an elevated ball or bump is placed over the stitch bond in order to secure the bond and provide higher integrity bond 308.

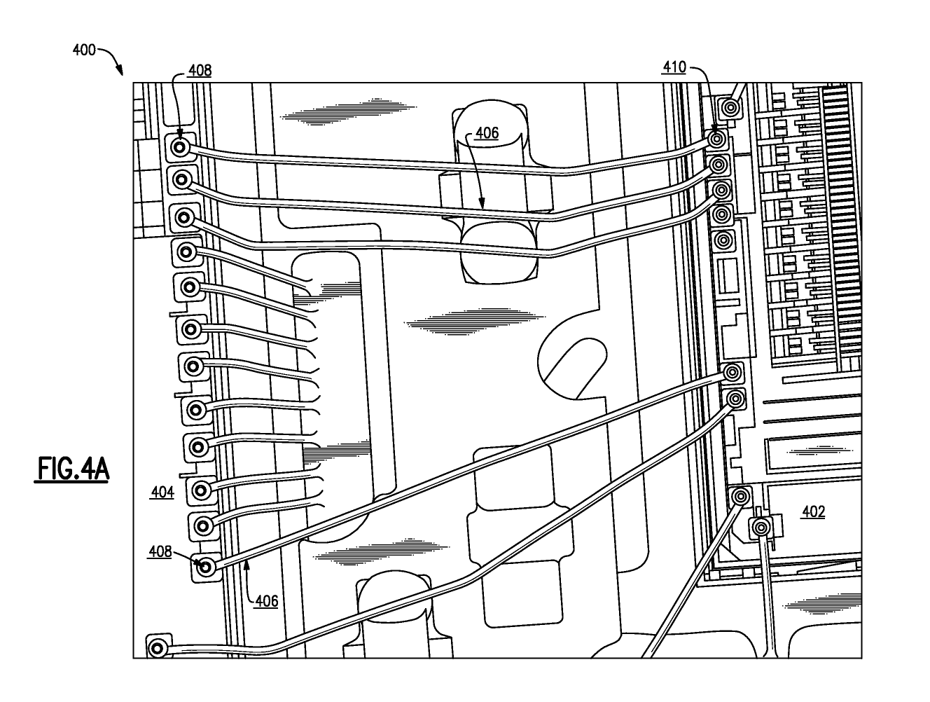

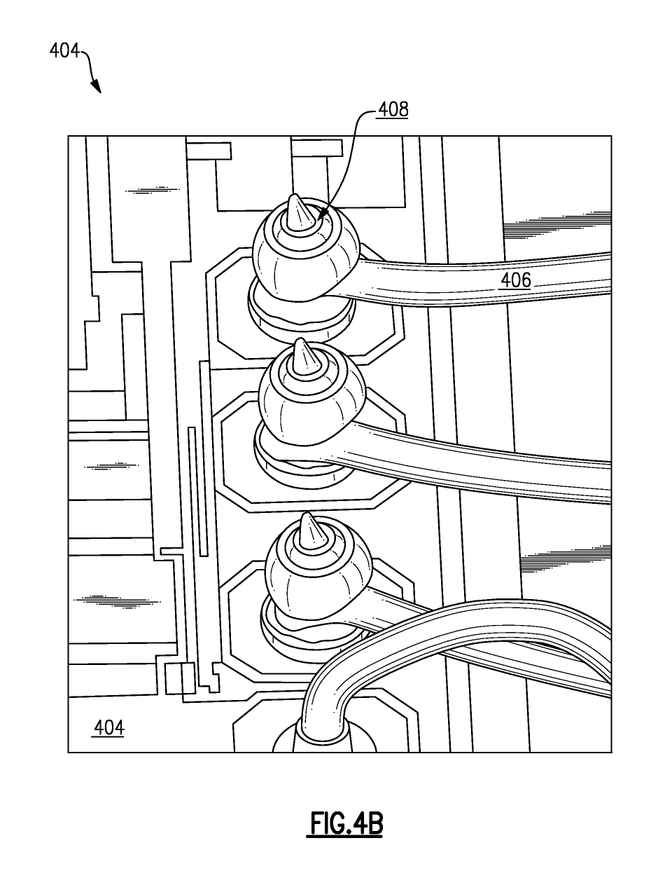

FIGS. 4A-4C illustrate wire bond interconnections 400 of two dies using long wires in accordance with aspects of the present disclosure. As is shown in FIG. 4A, two dies 402 and 404 are interconnected by conductive wires 406. In certain embodiments, interconnections between components that are spaced farther away, so that longer wires are used (e.g., approximately 1.4 mm or greater, 1.5 mm or greater, and the like), can be particularly problematic for stitch bonding (e.g., result in high resistance or lower current conductivity of the bonds) that does not utilize elevated bumps. Such bonds are illustrated in FIGS. 1A-1C.

Conductive bonds 410 are formed on the connectors of the die 404, and conductive bonds 408 are formed on the connectors of the die 408. As is illustrated in FIGS. 4B and 4C, a conductive ball or bump is placed over the stitch bond in order to provide a more secure and higher integrity bond 408. In some embodiments, bond 410 can be formed in a similar manner. In other embodiments, bond 410 can be a conventional bond, such as a ball bond formed by applying one or more of ultrasonic energy, pressure, and heat.

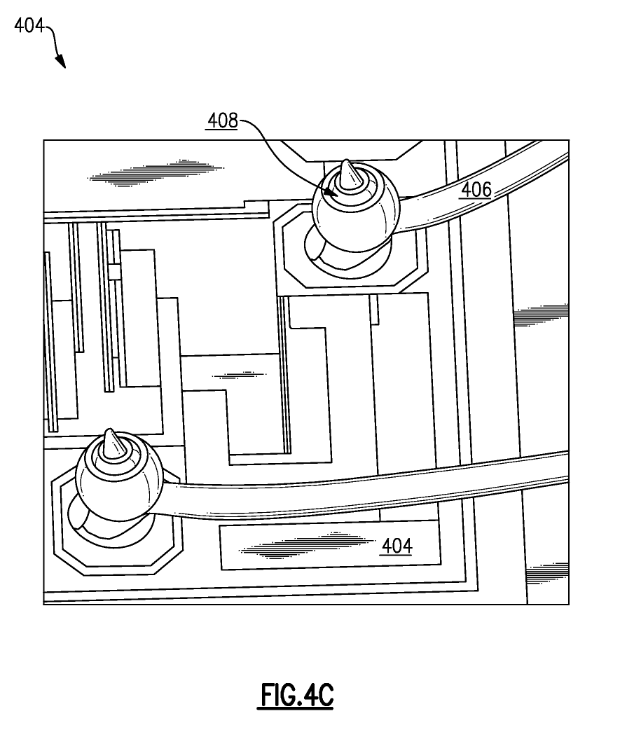

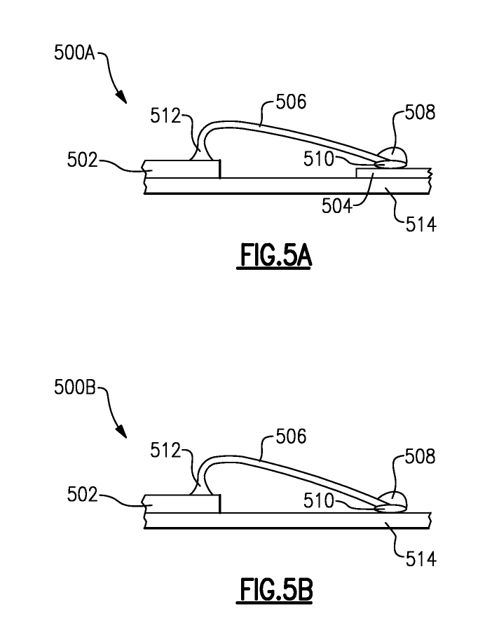

FIGS. 5A-5B illustrate wire bond interconnections in accordance with aspects of the present disclosure. FIG. 5A shows an interconnection 500A between two dies 502 and 504. The dies can be supported by a substrate 514. As is illustrated, a conductive wire 506 connects respective contacts of dies 502 and 504. In some embodiments, the conductive wire 506 is a gold wire. Bond 512 (e.g., a conventional ball bond) can be formed to connect the wire to the contact of the die 502. A ball 510 can be placed over the contact of die 504, and a stitch bond can be formed on the contact of the die 504. The stitch bond can be secured by an elevated bump 508, thus forming a strong, reliable, uniform, and high integrity bond. In certain embodiments, more than one elevated bump can be placed over the stitch bond, thus increasing the integrity of the bond.

FIG. 5B shows an interconnection 500B between a die 502 and substrate 514, which supports the die 502. As is illustrated, a conductive wire 506 connects respective contacts of the die 502 and the substrate 514. Bond 512 (e.g., a conventional ball bond) can be formed to connect the wire to the contact of the die 502. A ball 510 can be placed over the contact of the substrate 514, and a stitch bond can be on the contact of the substrate 514. The stitch bond can be secured by an elevated bump 508, thus forming a robust, reliable, uniform, and high integrity bond. In certain embodiments, more than one elevated bump can be placed over the stitch bond, thus increasing the integrity of the bond.

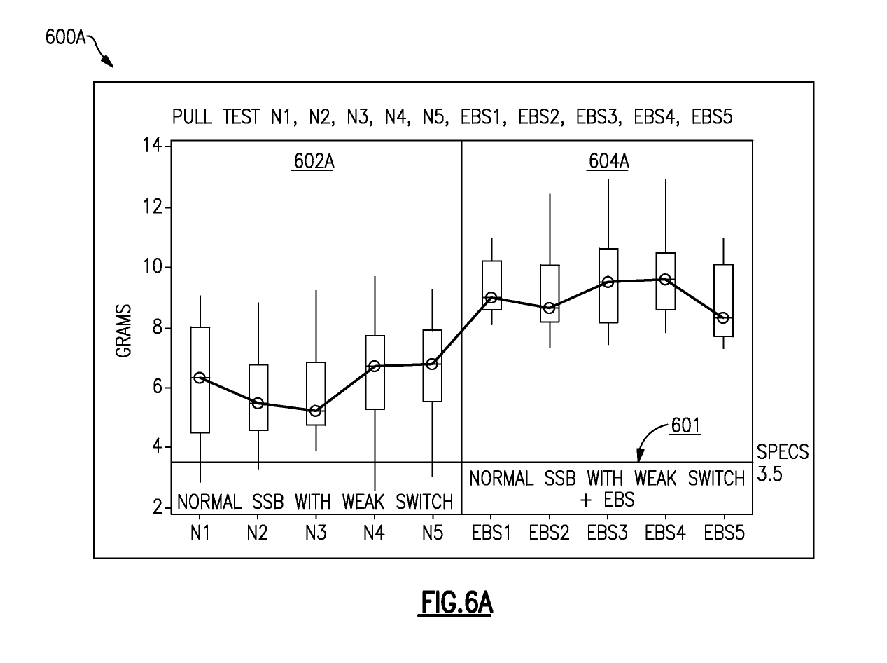

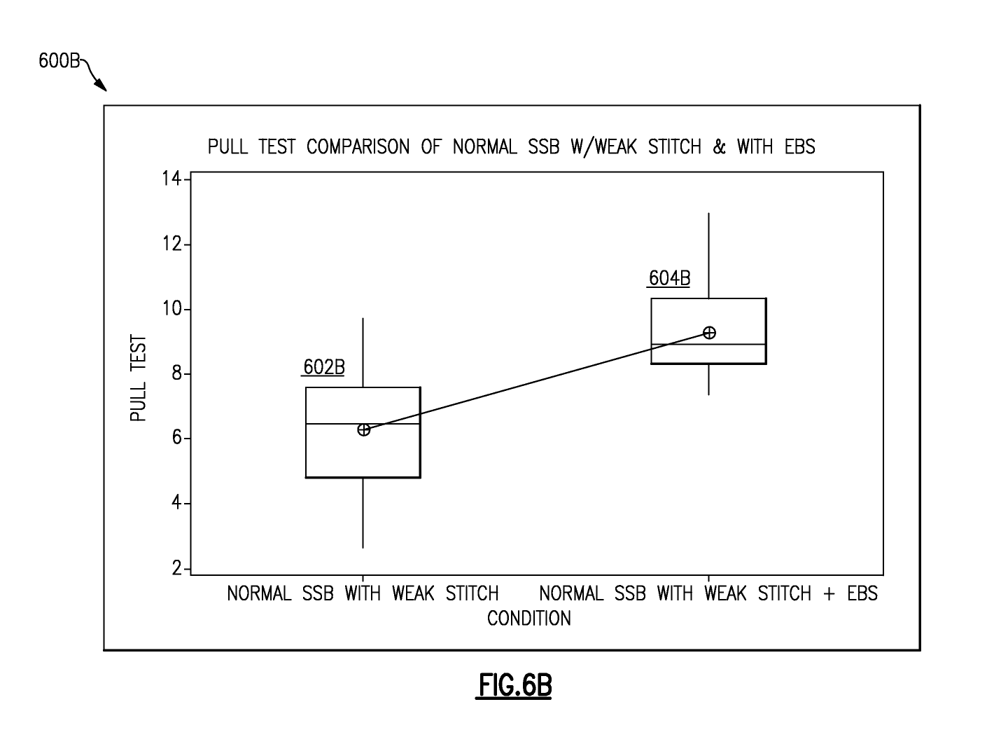

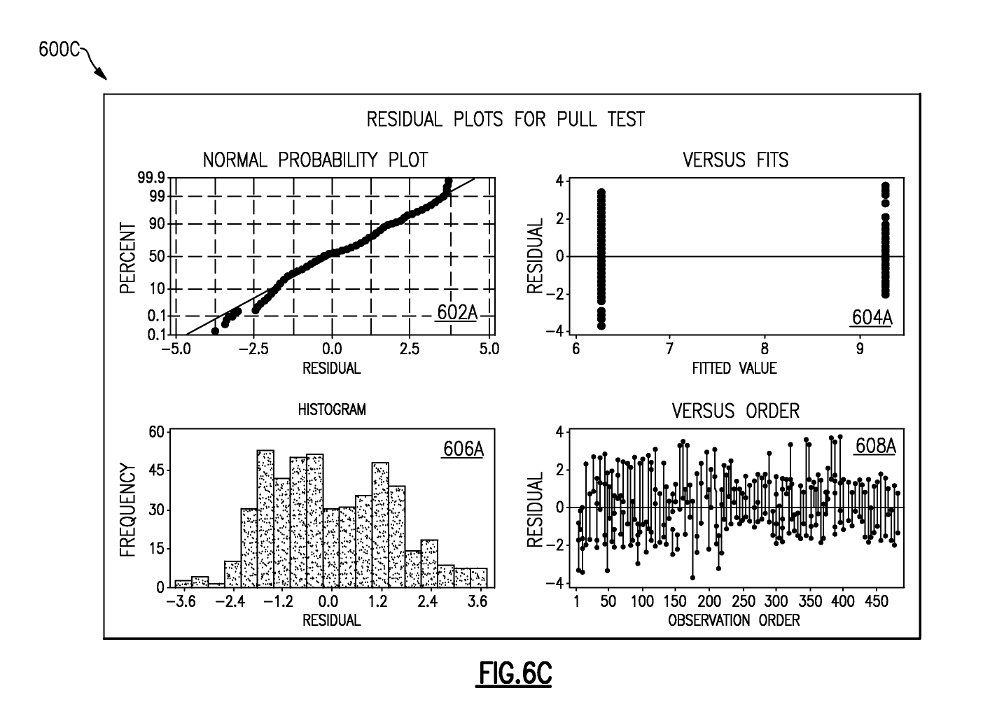

FIGS. 6A-6B illustrate test results of wire bond interconnections in accordance with aspects of the present disclosure. In some embodiments, pull testing involves physically lifting the wire that interconnects two components and determining whether the wire breaks at any of the bonds or in between the bonds, the bonds break, the bonds otherwise dislodge or lift off, etc. For example, a pull test using 3.5 grams of pull force can be utilized in 0.8 mm gold wire bonding process (e.g., wire diameter of 0.8 mm). In certain embodiments, other suitable pull forces can be used depending on the parameters of wire bonding process.

FIG. 6A shows a comparison 600A between pull test results performed on stitch bonds (e.g., bonds formed as is illustrated in FIGS. 1A-1C) 602A and on stitch bonds secured by elevated bumps 604A. Several bonds of each type (stitch—N1 through N5 and stitch secured by an elevated bump—EBS1 through EBS5) are illustrated. The y-axis reflects a maximum pull force (in grams) withstood by a particular bond. As is illustrated by a horizontal line 601, the bonds are specified for at least 3.5 grams of pull force. Wire pull test results 602A and 602B demonstrate that bonds secured by elevated bumps are stronger and more robust because these bonds withstood, on the average, pull forces of about 8-9 grams before the bond broke, was lifted or dislodged, or otherwise became unreliable.

In addition, bonds secured by elevated bumps have lower variances in bond strengths, as is illustrated by a smaller variance of graph 604A in relation with graph 602A. Hence, bonds secured by elevated bumps are more consistent. In certain embodiments, bonds secured by elevated bumps withstand an average pull force of approximately 9.25 grams at approximately 1.3 sigma (e.g., with confidence greater than 80%). In some embodiments, bonds secured by elevated bumps are stronger, more robust, and more consistent than stitch bonds not secured by elevated bumps.

FIG. 6B shows a comparison 600B between wire pull test results for weak stitch SSB bonds 602B and weak stitch SSB bonds secured by elevated bumps 604B. The y-axis reflects maximum pull force (in grams) withstood by a particular bond. As is illustrated, bonds secured by elevated bumps withstand greater pull force (e.g., approximately 9 grams) compared to bonds not secured by an elevated bump (e.g., approximately 7 grams). In some embodiments, bonds secured by elevated bumps are stronger, more robust, and have higher overall integrity.

FIG. 6C shows residual plots 600C for pull tests according to some aspects. In some embodiments, these plots can confirm validity of regression analysis, such as linear regression analysis. As is illustrated by normal probability plot 602A, residual values (e.g., differences between observed values and values predicted by a regression model) for wire pull test results obtained for bonds secured by elevated bumps closely follow normal distribution. This is also illustrated in graph 606A. As is illustrated in graph 604A, in some embodiments, bonds secured by elevated bumps withstand an average pull force greater than 9 grams, while bonds not secured by elevated bumps withstand an average pull force slightly above 6 grams. As is shown in graph 608A, residual values are plotted against observation order. The illustrated pattern confirms that errors are independent. In certain embodiments, graphs 602A, 604A, 606A, and 608A confirm correctness of the assumptions made, regression model, and obtained data.

### Automated Improved Wire Bonding

In some embodiments, wire bonding using elevated bumps can be automated by using a wire bonding machine (also known as wire bonders), which can be used to electrically interconnect two electrical contact points using wire and a combination of heat, pressure, and ultrasonic energy. In the wire bonding process, an automated tool is programmed to feed a wire through a capillary (or tool, wedge, tip), which forms the bonds. A ball bond can be formed by melting the wire before bonding it to the contact, and a stitch bond can be formed by pressing the wire against the surface of the contact. Bonds can be formed by application of one or more of ultrasonic energy, pressure, heat, etc.

In some embodiments, securing bonds with elevated bumps can be integrated into the wire bonding process performed by a particular wire bonding machine. While in certain embodiments wire bonding machines with higher bonding accuracy or precision are preferred for forming elevated bump bonds, such as Icon or Icon ProCu manufactured by Kulicke & Soffa, Eagle or Eagle Xterme manufactured by ASM, other types of wire bonding machines can be used.

In some aspects, the following tools and materials can be used to form elevated bump bonds using a wire bonding machine. Window clamp (a part of a lead frame wire bonding clamping assembly used to clamp lead frame leads to stabilize them) can be selected depending on the type and model of the wire bonding machine. Heater block insert (a part of the lead frame wire bonding clamping assembly) can also be selected depending on the type and model of the wire bonding machine. Capillary can be selected depending on particular requirements of the wire bonding process (e.g., bond pad size, bond pad pitch, type of wire, wire diameter, bonding surfaces, loop height, loop length, etc.). Gold wire can be used, and the diameter of the wire can be selected depending on particular requirements of the wire bonding process (e.g., types of bonds formed, die sizes, die positioning, etc.).

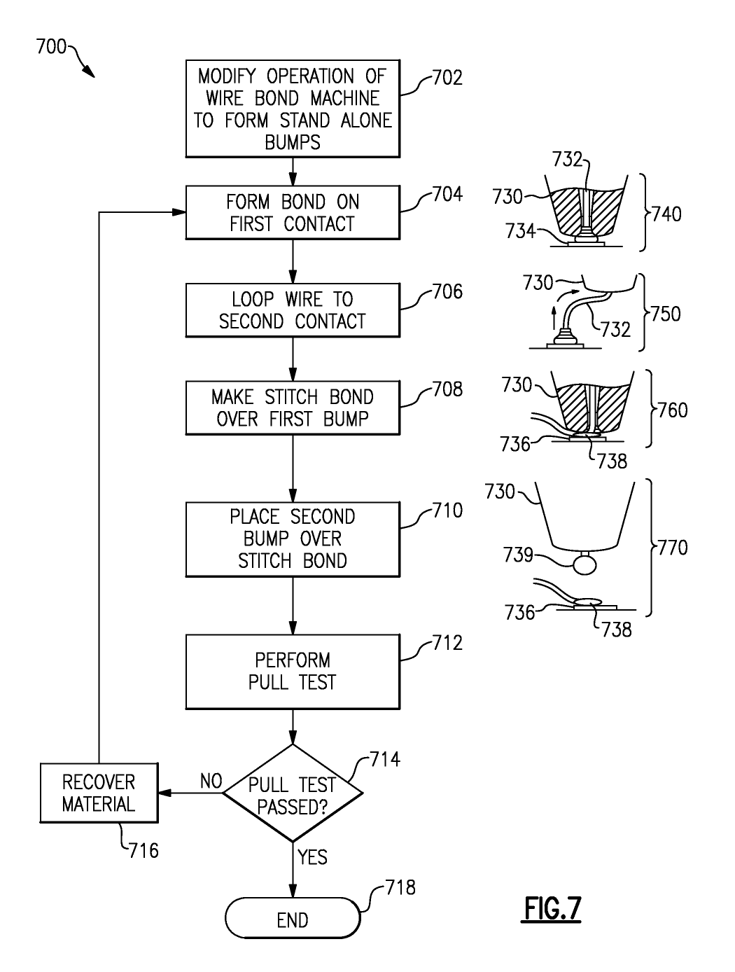

FIG. 7 illustrates a process 700 of forming wire bond interconnections in accordance with aspects of the present disclosure. In some embodiments, the process 700 can be performed by a wire bonding machine, such a high precision wire bonding machine. The process 700 starts at block 702 where the operation or programming of the wire bonding machine can be modified so that the machine (e.g., through a capillary 730) is configured to form stand alone bumps, such as elevated bumps. In block 704, the process forms a bond on the first contact, which can be a die contact, substrate contact, etc. As is illustrated in 740, the bond can be formed by melting the wire 732, such as a gold wire, before bonding it to the contact 734. In block 706, the process 700 operates the capillary to move the wire to a second contact, which can be a die contact, substrate contact, etc. This is illustrated in 750, where the capillary 730 loops the wire 732 to the second contact.

In block 708, the process 700 can form a first bump (e.g., by melting the wire) on the second contact, and form a stitch bond over or using the bump. As is illustrated in 760, the capillary 730 forms a stitch bond over or using the first ball 738 placed on the second contact 736. In some embodiments, the stitch bond can be formed directly on the second contact without the use of the first ball 738. In block 710, the process 700 can secure the stitch bond with an elevated bump. As is illustrated in 770, the capillary 730 forms a second ball 739 and secures the stitch bond with the second contact 736. The second ball can be formed from the same wire 732 or a different wire.

In certain embodiments, once the interconnection between the first and second contact has been formed, the process 700 can test the integrity or quality of the interconnection. In block 712, the process 700 can perform a pull test (or any other suitable test) with suitable criteria, such as pulling force. In block 714 the process 700 can determine whether the interconnection passed the pull test (e.g., the wire did not break, none of the bonds broke or dislodged, or the like). If the pull test was passed, the process can determine that a suitably strong interconnection was formed between the first and second contacts, and the process can terminate in block 718. In some embodiments, the process can loop back to block 704, and form an interconnection between next pair of contacts. If the process 700 determines in block 714 that the pull test failed, the process can transition to block 718 where material can be recovered. In certain embodiments, the process 700 can recover one or more of the wire (e.g., gold wire), bumps, etc. The recovered material can be reused for forming interconnections. The process 700 can then transition 704, and attempt forming the interconnection again.

In some aspects, forming wire bond interconnections can be performed using a wire bonding machine using the following process. A window clamp and insert can be installed. A suitable capillary can be installed or old capillary can be replaced. Ultrasonic calibration (e.g., USG calibration) can be performed. Depending on the requirements, bond off center or bond centering operation can be performed. The machine can be programmed or the programming can be modified to form a stand along bump (e.g., elevated bump) on die contacts or lead contacts. The bond position (e.g., elevated bump bond position) can be moved to the center of SSB, BSOB, or SOB wire connection (e.g., center of the stitch bond). Suitable bond parameters can be selected, including current, time, ultrasonic intensity, temperature, etc.

The process can bond the first wire (e.g., make interconnections between a first set of contacts) and center the bump to the camera of the wire bonding machine. The process can continue until all contacts (e.g., all die contacts) have been bonded. The process can perform a wire pull test (or any other suitable test) to check the integrity of the bond(s). If the process determines that the pull test was passed (e.g., the bond(s) have adequate strength), the wire machine can be programmed to proceed in automated mode, such as auto-bonding mode. In certain embodiments, the process can adjust and optimize bonding parameters if the pull test failed. Also, if the pull test failed, the process can recover the bonding material (e.g., wire, bumps, etc.).

Devices and Modules with Improved Wire Bonding

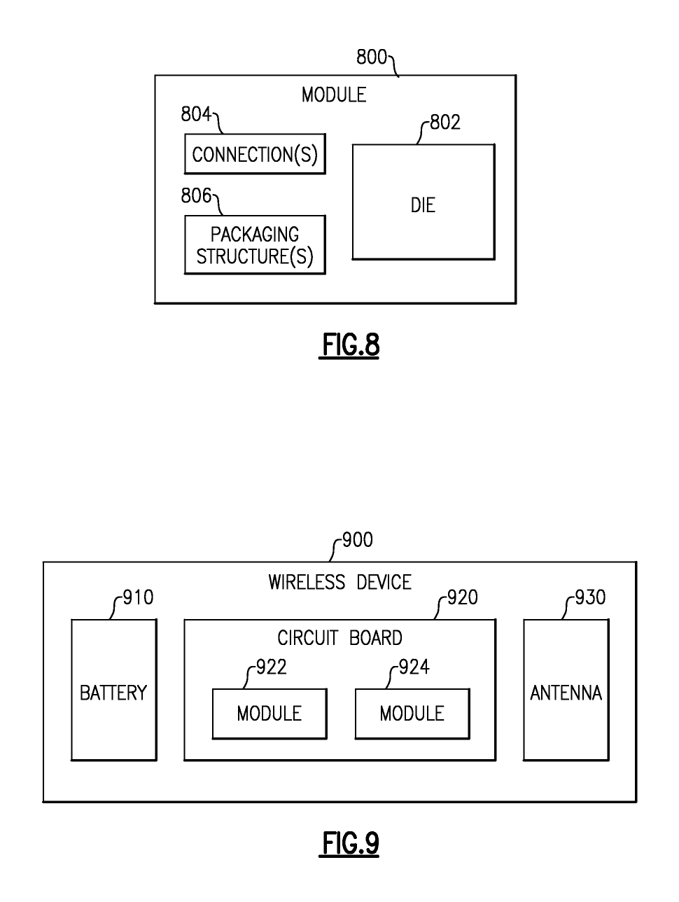

FIG. 8 illustrates a module 800 in accordance with aspects of the present disclosure. As is shown, in some embodiments, a die 802 can be part of a packaged module 800. The module or package 800 can also include a packaging substrate, such as a laminate substrate. The substrate can support the die 802. The module 800 can also comprise one or more connections 804 to facilitate providing signals to and from the die 802. The module 800 can also include various packaging structures 806. For example, an overmold structure can be formed over the die 802 to provide protection from external elements. The module 800 can include other components, such as die(s), RF device(s), RF shield(s), etc.

In some embodiments, the module can comprise one or more contacts (not shown), which can be interconnected to the connection(s) 804 using elevated bumps. A wire can interconnect the die 802 and connections(s) 804 by being bonded to a die contact by a stitch bond formed over a first ball placed on the die contact and a ball bond formed by a second ball placed over the stitch bond. In certain embodiments, the connection(s) 804 can be formed on the substrate, and interconnections can be formed between the die 802 and the substrate.

FIG. 9 illustrates a wireless device 900 in accordance with aspects of the present disclosure. The wireless device 900 can include a substrate (e.g., circuit board) 920, which supports one or more modules 922 and 924. In certain embodiments, modules 922 and 924 can be packaged as described above in connection with the module 800. The wireless device 900 is illustrated as including a battery 910 for powering the device 900 and an antenna 930 for transmitting and receiving signals wirelessly. The wireless device 900 can further include other components, such as a module, die, transceiver circuit, processor, display, I/O interface, etc.

In some embodiments, the modules 922 and 924 can be interconnected by a wire bonded using an elevated bump. For example, the wire can be bonded to a contact of the module 922 by a stitch bond formed over a first ball placed on the contact and a ball bond formed by a second ball placed over the stitch bond. In certain embodiments, one or both modules 922 and 924 can be interconnected with the circuit board 920 using elevated bump(s).

### TERMINOLOGY

Unless the context clearly requires otherwise, throughout the description and the claims, the words “comprise,” “comprising,” “include,” “including,” “have,” “having,” and the like are to be construed in an inclusive sense, as opposed to an exclusive or exhaustive sense; that is to say, in the sense of “including, but not limited to.” The term “coupled” is used to refer to the connection between two elements, the term refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the present disclosure using the singular or plural number may also include the plural or singular number respectively. The words “or,” “and,” and “and/or” used in reference to a list of two or more items cover all of the following interpretations of the word: any of the items in the list, all of the items in the list, and any combination of the items in the list.

The present disclosure is not intended to be exhaustive or to limit the invention to the precise form disclosed. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings provided herein can be applied to other systems, not necessarily the system described above. The elements and acts of the various embodiments described above can be combined to provide further embodiments.

Conditional language used herein, such as, among others, “can,” “might,” “may,” “e.g.,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A method of forming a wire bond connection between a first contact and a second contact using a wire bonding machine, the method comprising:
bonding a wire to the first contact;
placing a first ball on the second contact;
forming a stitch bond to connect the wire to the second contact, the stitch bond formed over the first ball; and
forming a ball bond by placing a second ball over the stitch bond.

2. The method of claim 1 further comprising performing an integrity test of the connection between the first contact and the second contact.

3. The method of claim 2 further comprising recovering the wire for reuse in forming a wire bond connection in response to determining that the integrity test had failed.

4. The method of claim 3 wherein the integrity test is a wire pull test.

5. The method of claim 1 wherein the first contact is a contact of a substrate and the second contact is a contact of a die.

6. The method of claim 1 wherein the first contact is a contact of a first die and the second contact is a contact of a second die.

7. The method of claim 1 wherein the wire is a gold wire.

8. The method of claim 1 wherein at least one of the bonding, the placing, the forming of the stitch bond, and the forming of the ball bond is performed by an automated wire bonding machine.

9. The method of claim 8 wherein substantially all of the bonding, the placing, the forming of the stitch bond, and the forming of the ball bond are performed by an automated wire bonding machine.

10. A chip package comprising:
a substrate configured to receive a plurality of components, the substrate including a substrate contact;
a first die supported by the substrate, the first die including a first die contact; and
a wire interconnecting the first die and the substrate, the wire bonded to the first die contact by a stitch bond formed over a first ball placed on the first die contact and a ball bond formed by a second ball placed over the stitch bond.

11. The chip package of claim 10 wherein the wire is a gold wire.

12. The chip package of claim 10 wherein the substrate includes a laminate substrate.

13. The chip package of claim 10 further comprising an overmold implemented over the substrate, the die, and the wire.

14. The chip package of claim 10 wherein the first die includes a radio-frequency (RF) circuit.

15. The chip package of claim 10 further comprising a second die supported by the substrate, the second die including a second die contact.

16. The chip package of claim 15 further comprising a wire interconnecting the first die and the second die, the wire bonded to the second die contact by a stitch bond formed over a first ball placed on the second die contact and a ball bond formed by a second ball placed over the stitch bond

17. A wireless device comprising:
an antenna configured to transmit and receive signals;
a transceiver configured to facilitate the transmitting and receiving of the signals; and
a circuit board including a first die having a first die contact, a second die having a second die contact, and a wire interconnecting the first die and the second die, the wire bonded to the second die contact by a stitch bond formed over a first ball placed on the second die contact and a ball bond formed by a second ball placed over the stitch bond.

18. The wireless device of claim 17 wherein the wire is a gold wire.

19. The wireless device of claim 17 further comprising a battery configured to power the wireless device.

20. The wireless device of claim 17 wherein the wireless device is a cellular phone.
